(19) United States
(12) Patent Application Publication
(10) Pub. No.: US 2013/0240894 A1
(43) Pub. Date: Sep. 19, 2013

(54) Overvoltage Protection Device for Compound Semiconductor Field Effect Transistors

(71) Applicants: Hans Joachim Würfl, Zeuthen (DE); Eldad Bahat-Treidel, Berlin (DE); Chia-Ta Chang, New Taipei City (TW); Oliver Hilt, Schoneiche (DE); Rimma Zhytnytska, Berlin (DE)

(72) Inventors: Hans Joachim Würfl, Zeuthen (DE); Eldad Bahat-Treidel, Berlin (DE); Chia-Ta Chang, New Taipei City (TW); Oliver Hilt, Schoneiche (DE); Rimma Zhytnytska, Berlin (DE)

(21) Appl. No.: 13/418,833

(22) Filed: Mar. 13, 2012

(51) Int. Cl. H01L 29/20; H01L 21/335; H01L 29/78

(52) U.S. Cl. 257/76; 257/355; 438/172; 257/E29.255; 257/E29.089; 257/E21.403

(57) ABSTRACT

An overvoltage protection device for compound semiconductor field effect transistors includes an implanted region disposed in a compound semiconductor material. The implanted region has spatially distributed trap states which cause the implanted region to become electrically conductive at a threshold voltage. A first contact is connected to the implanted region. A second contact spaced apart from the first contact is also connected to the implanted region. The distance between the first and second contacts partly determines the threshold voltage of the overvoltage protection device.

### FIELD OF TECHNOLOGY

The present application relates to overvoltage protection, in particular overvoltage protection for compound semiconductor field effect transistors.

### BACKGROUND

Power silicon-based field effect transistors (FETs) have an inherent parasitic p-n body diode in parallel with the transistor due to the n-type and p-type regions needed to form a Si FET. This parasitic body diode absorbs energy during gate or drain overvoltage events, providing some protection to the Si-based transistor from transient voltage spikes. Many types of compound semiconductor FETs have no such parasitic p-n diodes. For example, a GaN FET has no p-n junctions. Under inductive load switching conditions, current continues to flow in the GaN transistor even though the transistor is turned off and in a high resistance state. Absent some form of overvoltage protection which conventionally is in the form of a dedicated integrated circuit, the transistor will be damaged or destroyed under inductive load switching conditions.

### SUMMARY

According to an embodiment of a semiconductor device, the device includes a compound semiconductor material and a field effect transistor disposed in the compound semiconductor material. The transistor comprises a gate, a source, a drain, and a channel between the source and the drain controlled by the gate. The device further includes an overvoltage protection device electrically connected between the source and the drain of the transistor and formed by an implanted region of the compound semiconductor material. The overvoltage protection device is operable to become electrically conductive at a threshold voltage below a breakdown voltage of the transistor.

According to an embodiment of an overvoltage protection device for compound semiconductor field effector transistors, the device includes an implanted region disposed in a compound semiconductor material. The implanted region has spatially distributed trap states which cause the implanted region to become electrically conductive at a threshold voltage. A first contact is connected to the implanted region. A second contact spaced apart from the first contact is also connected to the implanted region. The distance between the first and second contacts partly determines the threshold voltage of the overvoltage protection device.

According to an embodiment of a method of manufacturing a semiconductor device, the method includes: forming a field effect transistor in a compound semiconductor material, the transistor comprising a gate, a source, a drain, and a channel between the source and the drain controlled by the gate; implanting ions into the compound semiconductor material to form an implanted region in the compound semiconductor material having spatially distributed trap states which cause the implanted region to become electrically conductive at a threshold voltage below a breakdown voltage of the transistor; and electrically connecting the implanted region between the source and the drain of the transistor.

Those skilled in the art will recognize additional features and advantages upon reading the following detailed description, and upon viewing the accompanying drawings.

### BRIEF DESCRIPTION OF THE FIGURES

The elements of the drawings are not necessarily to scale relative to each other. Like reference numerals designate corresponding similar parts. The features of the various illustrated embodiments can be combined unless they exclude each other. Embodiments are depicted in the drawings and are detailed in the description which follows.

FIG. 1 illustrates a schematic diagram of an overvoltage protection device coupled in parallel with a compound semiconductor FET.

FIG. 2 illustrates a top-down plan view of an overvoltage protection device coupled in parallel with a compound semiconductor FET according to different embodiments.

FIG. 3 illustrates a cross-sectional view of the embodiment of the overvoltage protection device along the line labelled ‘A’ in FIG. 2.

FIG. 4 illustrates the embodiment of FIG. 2 during an implantation process to form an implanted region of the overvoltage protection device.

FIG. 5 illustrates a cross-sectional view of the embodiment of the overvoltage protection device along the line labelled ‘B’ in FIG. 2.

FIG. 6 illustrates a cross-sectional view of the embodiment of the overvoltage protection device along the line labelled ‘C’ in FIG. 2.

FIG. 7 illustrates a cross-sectional view of yet another embodiment of the overvoltage protection device.

### DETAILED DESCRIPTION

Described next are embodiments of a compound semiconductor overvoltage protection device for high voltage circuit protection. The overvoltage protection device can be used to protect nitride-III based heterostructure field effect transistors (HFETs) from overvoltage events at the gate or drain of the transistor. The term HFET is also commonly referred to as HEMT (high electron mobility transistor), MODFET (modulation-doped FET) or MESFET (metal semiconductor field effect transistor). The terms compound semiconductor field effect transistor, HFET, HEMT, MESFET and MODFET are used interchangeably herein to refer to a field effect transistor incorporating a junction between two materials with different band gaps (i.e. a heterojunction) as the channel. For example, GaAs may be combined with AlGaAs, GaN may be combined with AlGaN, InGaAs may be combined with InAlAs, GaN may be combined with InGaN, etc. Also, transistors may have AlInN/AlN/GaN barrier/spacer/buffer layer structure. The term compound semiconductor field effect transistor as used herein may also refer to a field effect transistor fabricated using a single epitaxial compound semiconductor epitaxial such as epitaxial SiC. In each case, the overvoltage protection device can be used to protect transistors in power electronics application circuits from high voltage pulses and therefore is also referred to herein interchangeably as an electrostatic discharge device (ESDD).

The overvoltage protection device can be monolithically embedded with the transistor and utilize the same compound semiconductor epitaxial structure as the transistor. Alternatively, the overvoltage protection device can be implemented separately from the transistor as a stand-alone device on a different die. In either case, the overvoltage protection device is connected in parallel with the transistor between the source and drain of the transistor. The overvoltage protection device conducts current at a predefined threshold voltage which is lower than the transistor breakdown voltage. According to one embodiment, the threshold voltage of the overvoltage protection device is between 50% and 90% of the breakdown voltage of the transistor. Accordingly, the device conducts current prior to the transistor breakdown voltage and absorbs the dissipated energy the transistor is exposed to e.g. when switching inductive loads. Various parameters can be adjusted to set the desired threshold voltage of the protection device as will be described in more detail later herein, so that the device provides adequate protection without interfering with normal operation of the transistor under protection.

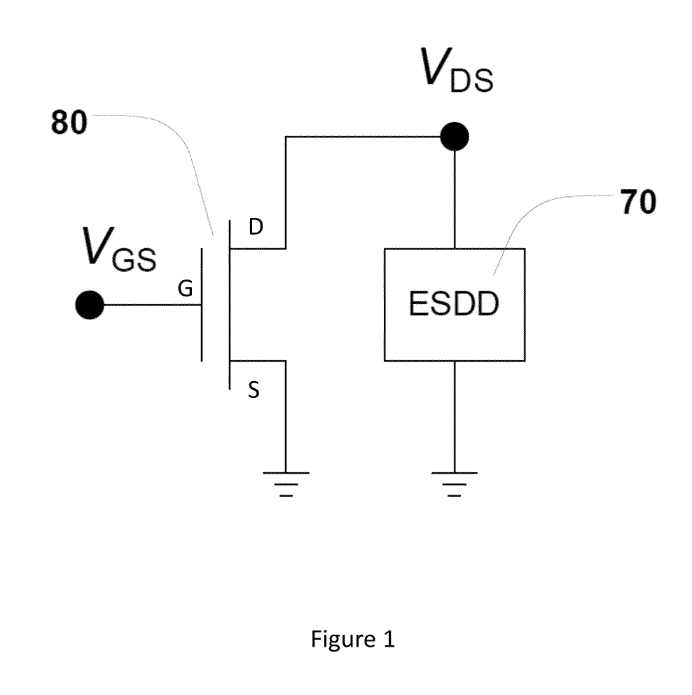

FIG. 1 illustrates a schematic circuit diagram of the overvoltage protection device 70 coupled in parallel with a compound semiconductor field effect transistor 80 between the source (S) and drain (D) terminals of the transistor 80. The transistor 80 also has and a channel between the source and the drain which is controlled by a gate (G). The overvoltage protection device 70 prevents overvoltage peaks at both the gate and drain terminals of the transistor 80, which is particularly important for power applications. For example, an excessive drain-to-source pulse (V_{DS}) might occur at the drain side if inductive loads are switched by the transistor 80. An excessive gate-to-source pulse (V_{GS}) also might occur at the gate. If such pulses lead to excessive electrical fields in critical device regions e.g. the gate area of a nitride-III based HFET, the transistor 80 can burn out or have a reduced lifetime. The overvoltage protection device 70 functions as an ESDD for high voltage switching transistors 80 by absorbing excessive voltage pulses at the gate and drain terminals.

The overvoltage protection device 70 acts as a pre-breakdown device in that the device 70 is designed to have a lower threshold voltage than the breakdown voltage of the transistor 80. When the electric field across the overvoltage protection device 70 becomes large enough, the device 70 is rendered conductive and creates a protective current path bypassing the transistor 80 when the transistor 80 is biased in an off-state condition i.e. is switched off. Below this threshold voltage, the overvoltage protection device 70 is inactive (non-conductive) and does not affect normal operation of the transistor 80. In order to provide efficient protection, the overvoltage protection device 70 has a significantly lower (active or on) resistance than that of the switched-off transistor 80. The resistance between the two terminals of the overvoltage protection device 70 can be adjusted by varying the implantation dose and device dimensions as explained in more detail later herein. The protection device 70 can be integrated with the transistor 80 on the same die, or can be a stand-alone device on a different die.

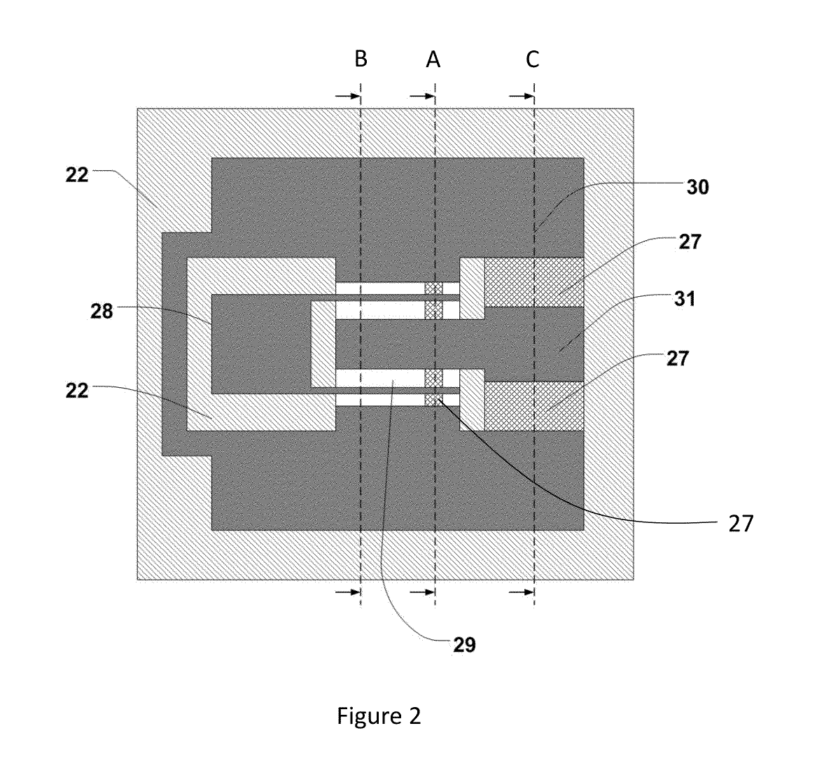

FIG. 2 shows a top-down plan view of different embodiments of the overvoltage protection device 70 integrated in the same epitaxial structure used to form two transistors which share common gate, drain and source terminals 28, 31, 30. Each of the embodiments is indicated by a different dashed line (A, B and C).

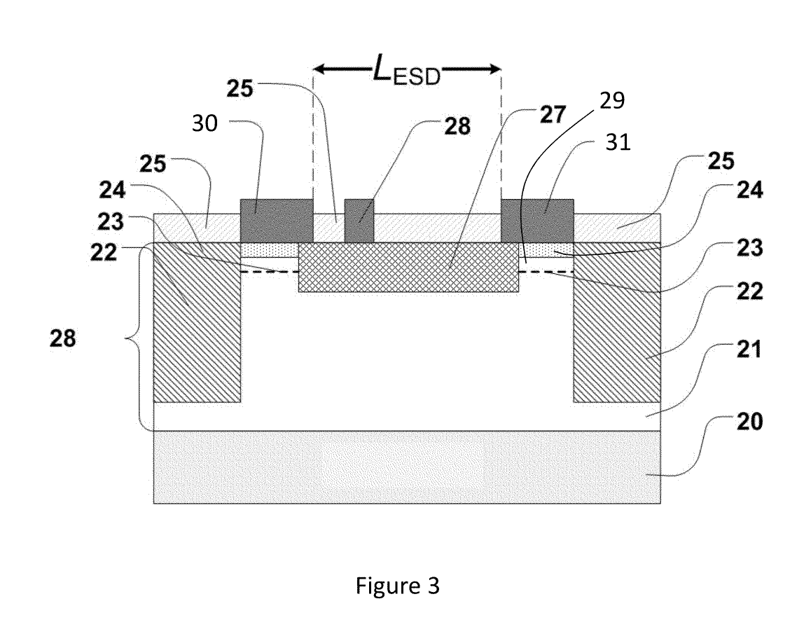

FIG. 3 shows a cross-sectional view of one embodiment along the dashed line labelled ‘A’ in FIG. 2 (only one transistor is shown in FIG. 3 for ease of illustration). According to this embodiment, an implanted region 27 of the overvoltage protection device 70 is formed in the active area 29 of the transistor and extends from an upper III-V barrier layer 24 into a lower III-V buffer layer 21.

In more detail, a semiconductor substrate 20 such as a Si, sapphire, SiC or GaN substrate is provided. An epitaxial compound semiconductor material 28 is formed on the substrate 20. The compound semiconductor material 28 can include one or more compound semiconductor layers, depending on the type of field effect transistor. For example, the compound semiconductor material 28 may be a single SiC epitaxial layer. For a nitride-III HFET, the compound semiconductor material 28 includes the resistive buffer layer 21 and the barrier layer 24. A nitride-III HFET can be implemented e.g. in GaN technology.

With GaN technology, the presence of polarization charges and strain effects result in the realization of a so-called “two-dimensional charge carrier gas” 23 which is a two-dimensional electron or hole inversion layer characterized by very high carrier density and carrier mobility. A two-dimensional electron gas (2DEG) or a two-dimensional hole gas (2DHG) which occurs in GaN technology due to polarization charges can be used as a conductive channel of a transistor, which is controlled by the gate terminal 28 of the transistor. In one embodiment, the transistor is a GaN HEMT, the buffer layer 21 comprises GaN and the barrier layer 24 comprises InGaN or AlGaN depending on the type of device i.e. whether a 2DEG (n-channel device) or 2DHG (p-channel device) forms the channel of the GaN HEMT. Other compound semiconductor technologies can also be used such as SiC, GaAs, etc.

In each case, the transistor has spaced apart drain and source terminals 31, 30 which are ohmic contacts (electrode pads) formed on the barrier layer 24. A passivation layer 25 is also provided on the barrier layer 24. The ohmic contacts 30, 31 also contact opposing sides of the implanted region 27 of the overvoltage protection device 70, and are laterally spaced apart by a distance L_{ESD} as shown in FIG. 3. This distance partly determines the threshold voltage of the overvoltage protection device 70 as described in more detail later herein. An inter-device isolation region 22 prevents crosstalk between adjacent devices. The implanted region 27 is connected between the drain and source ohmic contacts 30, 31 of the transistor, and forms the active area of the overvoltage protection device 70. The implanted region 27 of the overvoltage protection device 70 is formed by ion implantation. The implanted region 27 is designed to homogeneously conduct above a certain threshold voltage. The conductivity is due to trap-assisted hopping. That is, traps are created in the compound semiconductor material 28 by implantation of inert gas ions or dopant ions. If dopant atoms are used, subsequent processing temperatures are maintained low enough e.g. below 900° C. so that the majority of the dopant atoms remain inactive. In both cases, the two-dimensional charge carrier gas 23 is disrupted in the implanted region 27 due to the trap states.

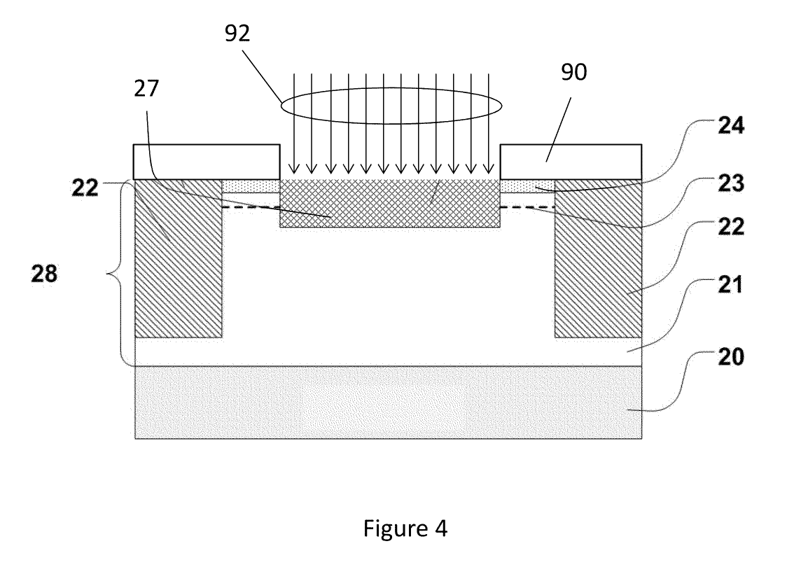

FIG. 4 shows the overvoltage protection device 70 during ion implantation and prior to contact formation and other subsequent processing. A mask 90 is applied to the compound semiconductor material 28 e.g. on the barrier layer 24 of a nitride-III device, so that only the area of the compound semiconductor material 28 to be implanted is exposed. The exposed area is heavily implanted with low energy inert gas ions 92 such as N, Ar, Xe, to create lattice damage in the unmasked part of the compound semiconductor material 28. The ion implantation obliterates the two-dimensional charge carrier gas 23 (2DEG for an n-channel device, 2DHG for a p-channel device) in the implanted compound semiconductor region 27. The implantation ions, energy level and dose are chosen such that the implanted semiconductor region 27 is highly conductive above a designed threshold voltage applied between the ohmic contacts 30, 31. In one embodiment, the implanted region 27 is operable to provide laterally homogeneous power dissipation when electrically conductive. The implanted semiconductor region 27 is not conductive below this threshold voltage. For a GaN device, the implantation energy is between 10 kV and 100 kV and the dose is between 10¹³ and 10¹⁶. The implantation energy and dose may vary for different compound semiconductor technologies and voltage applications. Alternatively, the implanted area 27 of the overvoltage protection device 70 can be formed by implanting the unmasked area of the compound semiconductor material 28 with dopant ions such as B, As, etc.

In either case, each individual ion produces point defects in the target crystal on impact such as vacancies and interstitials. These point defects can migrate and cluster with each other, resulting in extended defect clusters. If dopant ions instead of inert gas ions are used to form the implanted area 27 of the overvoltage protection device 70, processing temperatures post ion implantation are maintained below a maximum temperature e.g. 900° C. so that that enough of the dopant atoms remain inactive to disrupt the two-dimensional charge carrier gas 23 in the implanted region 27. The spatially distributed trap states created by ion implantation are spaced apart in the implanted region 27 of the overvoltage protection device 70 by an average distance small enough to permit trap-assisted charge carrier hopping between the trap states in sufficient quantity so that the implanted region 27 becomes electrically conductive at the threshold voltage of the overvoltage protection device 70 and non-conductive below this threshold voltage.

The threshold voltage of the overvoltage protection device 70 is a function of implantation energy level and dose as explained above. The threshold voltage of the overvoltage protection device 70 is also a function of the distance L_{ESD} between the contacts 30, 31 to the implanted region 27. Due to the tunneling effect, ESDDs with shorter L_{ESD} (e.g. between 2μ and 8 μm for nitride-III devices) reach the breakdown point quickly and may reach the threshold for the on-set of hopping conductivity more readily. The breakdown current can have quite an abrupt increase in this case. For ESDDs with longer L_{ESD} (e.g. between 8μ and 16 μm for nitride-III devices), the ESDDs with the highest dose level have smoother current curves and function similar to diodes with extremely high turn-on voltage. Based on such I-V characteristics and compared with the breakdown voltage of the transistor to be protected, ESDDs implanted with the highest ion dose level and with the longest L_{ESD} function the most effectively as a pre-breakdown protection device for high voltage switching transistors. The voltage where the breakdown current starts can be controlled in wide ranges by adjusting L_{ESD}.

That is, generally the breakdown voltage of the overvoltage protection device 70 increases with longer L_{ESD}. The ion implantation dose begins to affect the breakdown voltage above a particular L_{ESD}. Below this length, the ion implantation dose has little or no effect on breakdown voltage. For L_{ESD} lengths where ion implantation does have an effect on the breakdown voltage, the breakdown voltage initially increases at lower doses because the number of defects increases with increasing implantation dose. Thus more and more electrons (or holes for p-channel implementation) can be trapped in this region. For higher doses, the spacing between the defects reduces until a defect-assisted electrical conduction mechanism can take place. This in turn provides for a reduction of the breakdown voltage if the dose increases even further. Therefore, the breakdown voltage starts to decrease at a first critical dose level and dramatically drops at an even higher second critical dose level.

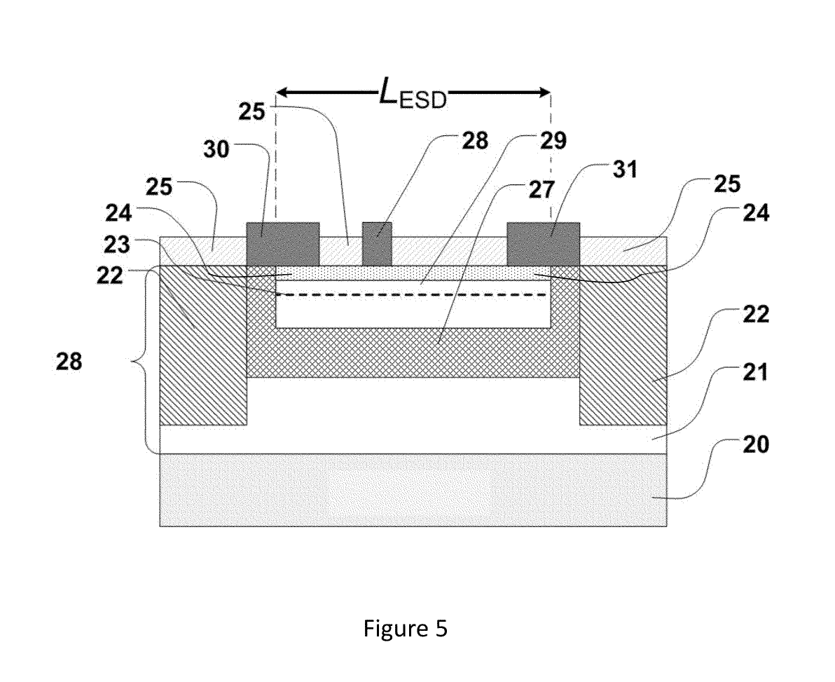

FIG. 5 shows a cross-sectional view of another embodiment along the dashed line labelled ‘B’ in FIG. 2 (only one transistor is shown in FIG. 5 for ease of illustration). According to this embodiment, the implanted region 27 of the overvoltage protection device 70 is buried entirely within the lower III-V buffer layer 27 below the two-dimensional charge carrier gas 23. Ion implantation can be used to form the buried implanted region 27 as previously described herein, however the implantation energy is increased compared to the embodiment shown in FIG. 4 so that the vast majority of implanted ions settle within the lower III-V buffer layer 27 below the two-dimensional charge carrier gas 23.

The buried implanted region 27 shown in FIG. 5 can be contacted in different ways. In one embodiment, the same or similar implantation dose used to form the buried implanted region 27 is used underneath the ohmic source and drain contacts 30, 31 to form vertical connections between the ohmic contacts 30, 31 and the buried implanted region 27. In another embodiment, mesa etching is performed down to the buried implanted region 27 and ohmic metallization is disposed in the mesa up to the top surface of the compound semiconductor material 28 where the source and drain contacts 30, 31 are provided. In yet another embodiment, ohmic contact annealing optimization can be performed depending on the specific ohmic metal used. In each case, the buried implanted region 27 is electrically connected to the ohmic drain and source contacts 30, 31 of the transistor through a vertical connection structure.

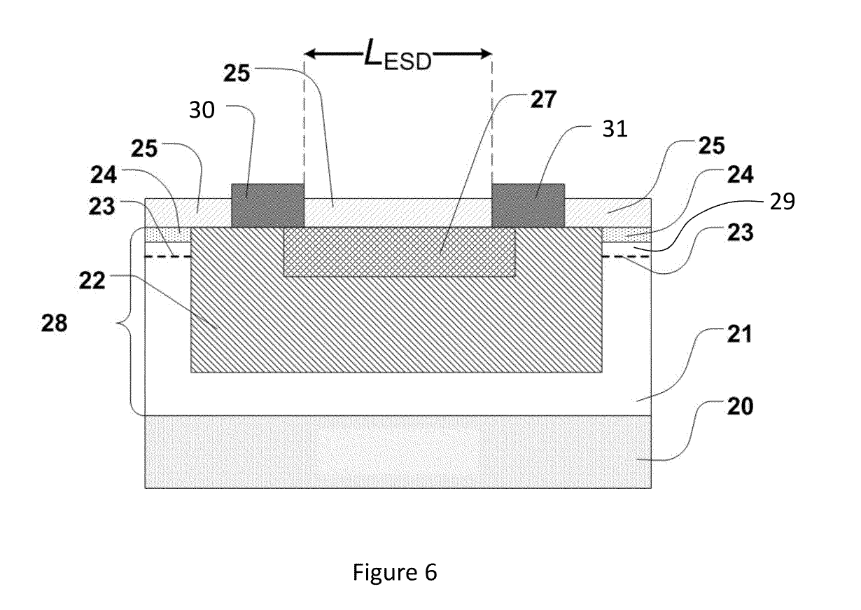

FIG. 6 shows a cross-sectional view of yet another embodiment along the dashed line labelled ‘C’ in FIG. 2 (only one transistor is shown in FIG. 6 for ease of illustration). According to this embodiment, the implanted region 27 of the overvoltage protection device 70 is formed in the device isolation region 22. As such, the implanted region 27 is surrounded laterally by the device isolation region 22 and separated from the active region 29 of the transistor by a portion of the device isolation region 22. The device isolation region 22 can be formed by mesa etching or multi-energy ion implantation. The implanted region 27 is more conductive under an applied voltage than the device isolation region 22, and therefore conducts above a certain threshold voltage to protect the transistor device.

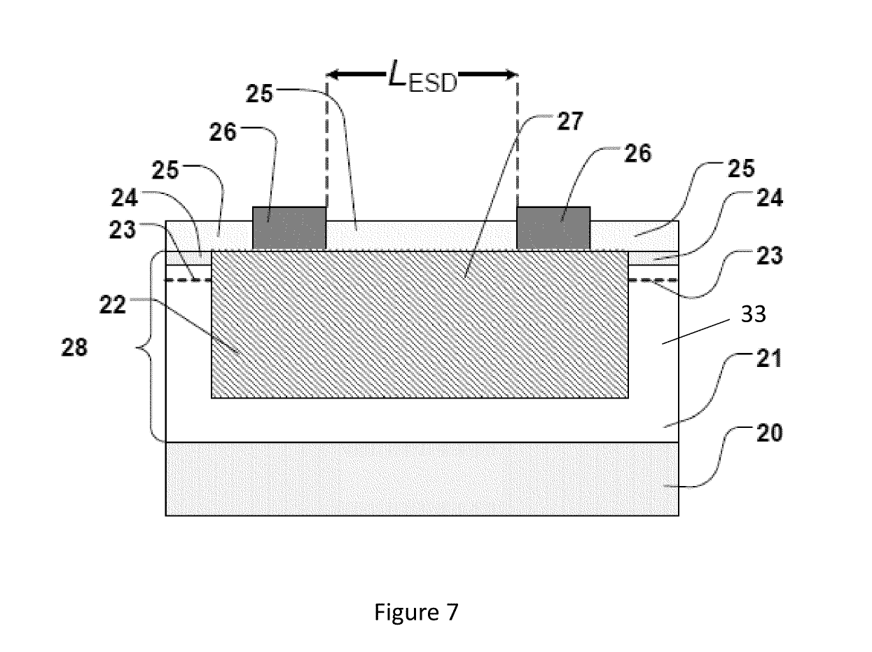

FIG. 7 shows a cross-sectional view of the overvoltage protection device 70 according to yet another embodiment. The implanted region 27 of the overvoltage protection device 70 is formed in an inactive region 33 of the compound semiconductor material 28 which is separated from the active region 29 of the transistor which is out of view in FIG. 7. Ohmic contacts 26 are provided to the implanted region 27. The ohmic contacts 26 can be part of the drain and source contacts 30, 31 of the transistor or separate contacts. In one embodiment, the overvoltage protection device structure shown in FIG. 7 is formed on a separate die than the transistor under protection and therefore the ohmic contacts 26 to the implanted region 27 are different than the drain and source contacts 30, 31 of the transistor.

Spatially relative terms such as “under”, “below”, “lower”, “over”, “upper” and the like, are used for ease of description to explain the positioning of one element relative to a second element. These terms are intended to encompass different orientations of the device in addition to different orientations than those depicted in the figures. Further, terms such as “first”, “second”, and the like, are also used to describe various elements, regions, sections, etc. and are also not intended to be limiting. Like terms refer to like elements throughout the description.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

It is to be understood that the features of the various embodiments described herein may be combined with each other, unless specifically noted otherwise.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A semiconductor device, comprising:
a compound semiconductor material;
a field effect transistor disposed in the compound semiconductor material and comprising a gate, a source, a drain, and a channel between the source and the drain controlled by the gate; and
an overvoltage protection device electrically connected between the source and the drain of the transistor and formed by an implanted region comprising spatially distributed trap states which cause the implanted region to become electrically conductive at a threshold voltage below a breakdown voltage of the transistor.

2. A semiconductor device according to claim 1, wherein the spatially distributed trap states are spaced apart in the implanted region by an average distance small enough to permit trap-assisted charge carrier hopping between the trap states in sufficient quantity so that the implanted region becomes electrically conductive at the threshold voltage of the overvoltage protection device.

3. A semiconductor device according to claim 1, wherein the compound semiconductor material comprises a first III-V semiconductor material and a second III-V semiconductor material on the first III-V semiconductor material, and wherein the first and second III-V semiconductor materials have different bandgaps such that a two-dimensional charge carrier gas arises in the first III-V semiconductor material close to the interface between the first and second III-V semiconductor materials.

4. A semiconductor device according to claim 3, wherein the implanted region extends from the second III-V semiconductor material into the first III-V semiconductor material.

5. A semiconductor device according to claim 3, wherein the implanted region is formed entirely within the first III-V semiconductor material below the two-dimensional charge carrier gas.

6. A semiconductor device according to claim 3, wherein the first and second III-V semiconductor materials each comprise nitride.

7. A semiconductor device according to claim 6, wherein the first III-V semiconductor material comprises GaN and the transistor is a high electron mobility transistor.

8. A semiconductor device according to claim 3, wherein the implanted region comprises inert gas ions which disrupt the two-dimensional charge carrier gas in the implanted region.

9. A semiconductor device according to claim 3, wherein the implanted region comprises inactive dopant ions which disrupt the two-dimensional charge carrier gas in the implanted region.

10. A semiconductor device according to claim 1, wherein the implanted region is operable to provide laterally homogeneous power dissipation when electrically conductive.

11. A semiconductor device according to claim 1, further comprising a first contact connected to a first terminal of the overvoltage protection device and a second contact spaced apart from the first contact and connected to a second terminal of the overvoltage protection device, wherein the distance between the first and second contacts partly determines the threshold voltage of the overvoltage protection device.

12. A semiconductor device according to claim 1, wherein the field effect transistor is formed in an active region of the compound semiconductor material and the semiconductor device further comprises a device isolation region isolating the transistor.

13. A semiconductor device according to claim 12, wherein the implanted region of the overvoltage protection device is formed in the device isolation region.

14. A semiconductor device according to claim 12, wherein the implanted region of the overvoltage protection device is formed in an inactive region of the compound semiconductor material separated from the active region by the device isolation region.

15. A semiconductor device according to claim 1, wherein the threshold voltage of the overvoltage protection device is between 50% and 90% of the breakdown voltage of the transistor.

16. A semiconductor device, comprising:
a compound semiconductor material;
an implanted region disposed in the compound semiconductor material and having spatially distributed trap states which cause the implanted region to become electrically conductive at a threshold voltage;
a first contact connected to the implanted region; and
a second contact spaced apart from the first contact and connected to the implanted region, the distance between the first and second contacts partly determining the threshold voltage.

17. A semiconductor device according to claim 16, wherein the implanted region comprises inert gas ions.

18. A semiconductor device according to claim 16, wherein the implanted region comprises inactive dopant ions.

19. A semiconductor device according to claim 16, wherein the spatially distributed trap states are spaced apart in the implanted region by an average distance small enough to permit trap-assisted charge carrier hopping between the trap states in sufficient quantity so that the implanted region becomes electrically conductive at the threshold voltage.

20. A method of manufacturing a semiconductor device, comprising:
forming a field effect transistor in a compound semiconductor material, the transistor comprising a gate, a source, a drain, and a channel between the source and the drain controlled by the gate;
implanting ions into the compound semiconductor material to form an implanted region in the compound semiconductor material having spatially distributed trap states which cause the implanted region to become electrically conductive at a threshold voltage below a breakdown voltage of the transistor; and
electrically connecting the implanted region between the source and the drain of the transistor.

21. A method according to claim 20, wherein the compound semiconductor material comprises a first III-V semiconductor material and a second III-V semiconductor material on the first III-V semiconductor material, and wherein the first and second III-V semiconductor materials have different bandgaps such that a two-dimensional charge carrier gas arises in the first III-V semiconductor material.

22. A method according to claim 21, wherein the ions are implanted with sufficient energy so that the implanted region is formed entirely in the first III-V semiconductor material below the two-dimensional charge carrier gas.

23. A method according to claim 21, wherein implanting the ions into the compound semiconductor material to form the implanted region comprises implanting a quantity of inert gas ions into the compound semiconductor material sufficient to disrupt the two-dimensional charge carrier gas in the implanted region.

24. A method according to claim 21, wherein implanting the ions into the compound semiconductor material to form the implanted region comprises implanting a quantity of inactive dopant ions into the compound semiconductor material sufficient to disrupt the two-dimensional charge carrier gas in the implanted region, and wherein each processing step subsequent to the ion implantation is performed below a predetermined temperature so that enough of the dopant atoms remain inactive and the two-dimensional charge carrier gas remains disrupted in the implanted region.

25. A method according to claim 21, wherein the ions are implanted into the compound semiconductor material with sufficient energy to form the implanted region entirely within the first III-V semiconductor material below the two-dimensional charge carrier gas.

26. A method according to claim 20, wherein the ions are implanted with sufficient energy and concentration so that the spatially distributed trap states are spaced apart in the implanted region by an average distance small enough to permit trap-assisted charge carrier hopping between the trap states in sufficient quantity so that the implanted region becomes electrically conductive at the threshold voltage of the implanted region.

27. A method according to claim 20, wherein the field effect transistor is formed in an active region of the compound semiconductor material, the method further comprising forming a device isolation region isolating the transistor.

28. A method according to claim 27, wherein the ions are implanted into the device isolation region so that the implanted region is formed in the device isolation region.

29. A method according to claim 27, wherein the ions are implanted into an inactive region of the compound semiconductor material separated from the active region by the device isolation region.

30. A method according to claim 20, wherein the transistor is a GaN transistor and the ions are implanted with an energy between 10 kV and 100 kV and at a dose between 10¹³ and 10¹⁶.
